(19) United States
(12) Patent Application Publication
(10) Pub. No.: US 2009/0188549 A1
(43) Pub. Date: Jul. 30, 2009

(54) Method of and apparatus for improved thermophotonic generation of electricity

(75) Inventor: Robert DiMatteo, Belmont, MA (US)

Correspondence Address: RINES & RINES, 24 Warren St., CONCORD, NH, 03301, US

(73) Assignee: MTVP Corporation

(21) Appl. No.: 12/011,677

(22) Filed: Jan. 29, 2008

(51) Int. Cl. H01L 31/04; H01S 5/00; H01L 33/00

(52) U.S. Cl. 136/253; 372/43.01; 257/E33.001

(57) ABSTRACT

A thermophotonic method and generator of photovoltaic current wherein preferably a thermal source supplemented by photon flux as generated in an interposed semiconductor LED or the like is vacuum-spaced from a photovoltaic semiconductor surface by a gap of the order of submicrons/microns.

### FIELD OF INVENTION

The present invention relates generally to the conversion of radiation into electricity by the photovoltaic effect, including directly from the sun (PV), or from an absorber or emitter drawing heat from the sun (TPV), or otherwise; being more specifically concerned with thermovoltaic current generation in which the radiation from the heat source or body is enhanced by an internal electrochemical potential difference (TPX) interposed between the heat source or emitter and the photovoltaic converter, such as an intermediate light-emitting diode (LED) source of photons or the like, as described, for example, in an article by N. P. Harder and H. L. Green entitled “Thermophotonics” appearing in Semiconductor Science and Technology, 18, (2003), p. 3270-1, and to improvements therein.

### BACKGROUND

The said article discloses that such TPX technique has a substantially higher theoretical conversion efficiency than TPV operation, and that the range of suitable band gap energies for TPX operation is greatly enhanced towards larger values over that of TPV. Such “super thermal” power density appears to result from the luminescent diode photon emission in the recombining of electron hole pairs and the permitting of photons equal to the band gap energy, even though the electron-hole pair has been injected into the diode with a bias voltage of only a fraction of the before-mentioned band gap. The excess energy involved takes the form of heat at the contacts with, for example, thin semiconductor layers and nanostructures later discussed, with the diode and its contacts being thermally connected to the hot body, and with the diode luminescence effecting radiating from the hot body at “super thermal” power densities across the gap or space to the photovoltaic surface.

Underlying the present invention is the consideration of the effects of this gap as the photon escapes the LED, transverses the gap, and enters the adjacent photovoltaic surface, there to be converted into electricity by the cell. One of the shortcomings of such TPX operation, indeed, is that not all the photons created by the LED luminescence reach the photovoltaic surface to be converted into electricity by the cell.

In the before-mentioned TPV technology, it has been discovered that if the hot body or source temperature is high enough, in excess of about 500° C., or above, considerable photon enhancement effects can be achieved in TPV by reducing the gap or space between the heat-emitter surface and the photovoltaic semiconductor surface to separations of the order of submicrons, and particularly when the gap is evacuated. This enhancement effect with high temperature heat sources, greater than about 500° C., have been earlier described in my previous U.S. Pat. Nos. 6,084,173 and 6,232,546 and in my patent publication number 2004/0231717A1 of Nov. 25, 2004, and in my paper entitled “Micron-gap Thermo photovoltaic (MTPV)” appearing in the Proceedings of the Fifth TPV Conference (2002), herein incorporated, by reference. Under conditions of the hot side emitter temperature in excess of 500° C., and with the micro or nano-gap separation to the photocell surface at the gap, enhanced conversion into electricity or power is produced.

At first blush, the possible applicability of such MTPV technology to the TPX field of the present invention may not be evident, or indeed deemed workable, particularly since the hot side emitter temperatures required are far too high for the use of TPX light emitting diodes or similar such lower temperature photon generators. While enhanced transfer occurs, there is no useful carrier generation. The present invention involves the adaptation, however, of gap reduction to the operation of TPX structures, with important modifications to such structures: One of the short-comings of a possible marriage of MTPV techniques with TPX structures is, as before stated, that many of the photons created in the LED do not flow from the diode semiconductor structure to, for example, the adjacent semiconductor photocell surface and are therefore not available for conversion into electricity by the photovoltaic surface.

In accordance with the present invention, nonetheless, the concept of reducing the gap to submicron dimensions is adopted—this time between an appropriate light emitter diode surface, (“hot” side but less than 500° C.) and a lower temperature photovoltaic cell surface (serving as a “cold” side with respect to the LED), and the TPX structure is adapted to permit the enhanced collection of photon flux created by the luminescence of the LED surface.

Considerable enhancement of TPX operation can now, in accordance with the present invention, fortuitously be created for low-temperature systems (about 200° C. or less), as compared with MTPV technology (500° C. and above), through the different phenomenon of collecting or capturing LED photon semiconductor surface emissions across an evacuated submicron gap to a juxtaposed adjacent photovoltaic surface disposed parallel with and coextensive with the semiconductor surface of the light-emitting diode structure.

### OBJECTS OF INVENTION

An object of the current invention, accordingly, is to provide a new and improved method of and apparatus for TPX systems that more efficiently utilize photon or other electromagnetic emissions from a relatively hot side to a juxtaposed relatively cold side of a TPX system.

A further object is to provide improved flow capture of photons generated by an LED or similar electromagnetic emitter structure by a juxtaposed photovoltaic surface and the like.

Still a further object is to provide a new and improved structure that will enable enhancement of photon flow from a relatively hot emitter side (LED) to a relatively cold photovoltaic side of a heat-to-electricity converter.

Another object is to modify the concept of evacuated submicron gap photovoltaic heat converters from MTPV technology so that it can be used to improve TPX operation and structures.

Other and further objectives will be explained hereinafter and are more particularly defined in the appended claims.

### SUMMARY OF INVENTION

From one of its broadest aspects, the invention embraces a method of thermophotonic generation of photovoltaic current in a relatively cool photovoltaic surface responsive to photon energy received from a radiation-emitting thermal source supplemented by photon flux as generated in an interposed light-emitting diode relatively “hot” surface, that comprises, juxtaposing said surfaces; evacuating the space therebetween; and enhancing such photon flux received from the light emitting diode surface upon the photovoltaic surface by adjusting said space to the order of submicrons.

Detailed designs and embodiments and best mode structures are hereinafter presented.

### DRAWINGS

The invention will now be described in connection with the accompanying drawings,

FIG. 1 of which is a schematic idealized and expanded diagram of a prior art TPX structure in generic form; and

FIG. 2 is a similar diagram embodying the improvements of the present invention in preferred form.

### DESCRIPTION OF PREFERRED EMBODIMENT(S)

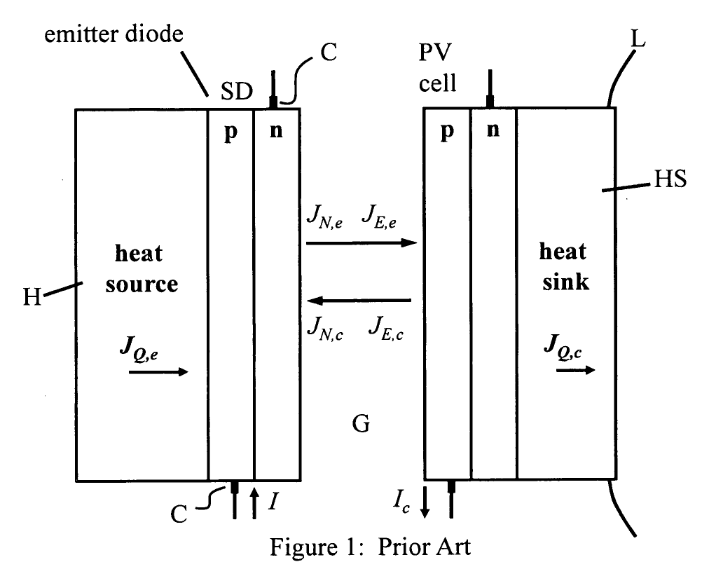

Referring to FIG. 1, a generalized schematic structure is there shown of a thermal photonic prior art structure (TPX) as described in said Harder and Green article. It embodies a heat source, so-labeled at H, (which may be the sun or an absorber of sun energy or any other suitable heat-emitting source or body, including combustion sources of heat), applying heat J to juxtaposed n-p semiconductor chip surfaces SD of an interposed LED or the like, spaced at gap G from a photovoltaic semiconductor chip or photovoltaic cell, so labeled at “PV cell”, intercepting the photon flux J emitted by the light-emitting diode across the gap G. Heat may also be applied to the LED by conduction or convection. The semiconductor surfaces n-p are shown in generalized schematic form, adapted to assume any practical geometrical configurations desired. They have applied electrical bias current I at leads and contacts C, in thermal connection with the heat-side source H—and with radiation fluxes shown by arrows J, including the associated photon luminescence of the LED. The photovoltaic surfaces are also shown in generalized form, with heat and photon energy flux from the interposed LED schematically represented at J, and the contacts and leads, shown at L, for the withdrawal of electricity from the photovoltaic cell at the heatsink side HS.

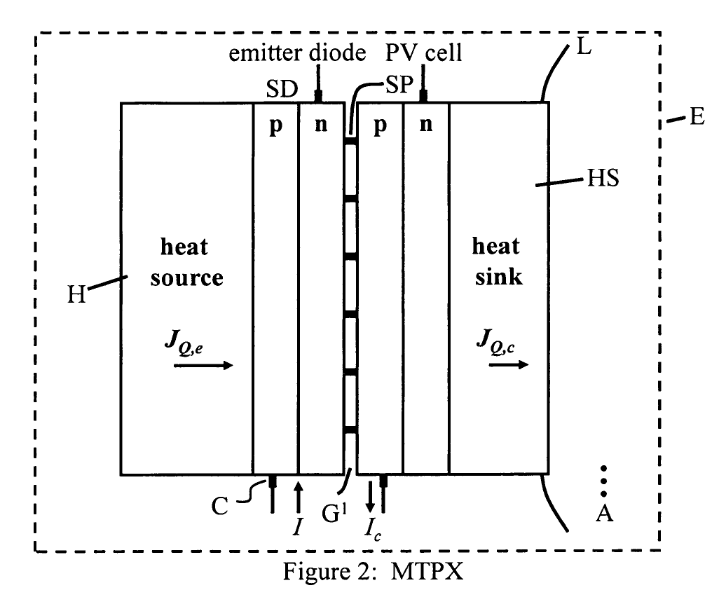

The present invention is shown in preferred form in FIG. 2, for much lower temperature conversion of thermal energy to electricity utilizing the TPX principles. In this connection, as shown in FIG. 2, the devices are enclosed in an evacuated enclosure or housing E, and the LED-to-PV cell gap G¹ is reduced to submicron or micron separation. The now juxtaposed contiguous photovoltaic and light-emitting diode surfaces are maintained at this juxtaposition, for example, by submicron heat-insulating spacers SP such as described in my previously cited patent publication of 2004 and in my referenced paper. Arrays of such TPX chips may be assembled in the same housing E, as schematically represented at A in FIG. 2. Not only may LED devices be used well below the 500° C. of MTPV technology—in fact of the order of 50-200° C.—but enhanced TPX operation can be now achieved from relatively low heat sources such as from the heat of laptop computer devices and the like.

Modified MPTV concepts may also be used to improve TPX operation of the invention as used for refrigeration, by the same mechanism of captured photon flux enhancement, but where the thermal energy transmitted by emitted photons are not replaced by adding heat to the LED side, as discussed in the said article. In this embodiment, the thermal energy that contributes to photon emission is not replaced by adding heat at H to the LED side, thus absorbing such heat and creating cooling.

The invention may also be applied to devices involving quantum coupling as in co-pending U.S. patent application Ser. No. 11/500,062, of common assignee herewith, wherein electrons in the emitting structure on the hot side are generated by electrical stimulation and then transitioned to a lower state, transferring energy to the cold side as involved in such electron stimulation.

Further modifications will also occur to those skilled in the art, and such are considered to fall within the spirit and scope of the invention as defined in the appended claims.

What is claimed is:

1. A method of thermophotonic generation of photovoltaic current in a relatively cool photovoltaic surface responsive to photon energy received from a radiation-emitting thermal source supplemented by photon flux as generated in an interposed light-emitting diode relatively hot surface, that comprises, juxtaposing said surfaces, evacuating the space therebetween, and enhancing the photon flux received from the light-emitting diode surface upon the photovoltaic surface by adjusting and maintaining said space to the order of submicrons.

2. The method of claim 1 wherein the relatively hot surface is of the order of 200° C. and less, and the light-emitting diode surface is operated by an internal electrochemical potential difference under externally supplied bias voltage.

3. A method of thermophotonic generation of photovoltaic current in a relatively cool photovoltaic surface responsive to photon energy received from a relatively hot surface source of photon flux, that comprises, juxtaposing said surfaces, evacuating the space therebetween, and enhancing the photon flux as received upon the photovoltaic surfaces by adjusting and maintaining said space to the order of submicrons.

4. The method of claim 3 wherein the relatively hot surface is of the order of 200° C. and less.

5. A thermophotonic photovoltaic current generator, having, in combination, a thermal source comprising a relatively hot photon-emitting surface and an adjacent and co-extensive relatively cool juxtaposed photovoltaic surface, with the space therebetween evacuated and adjusted to the order of submicrons.

6. A thermophotonic photovoltaic current generator, having, in combination, a thermal source comprising a relatively hot photon-emitting surface and an adjacent and co-extensive relatively cool juxtaposed photovoltaic surface, with the space therebetween evacuated and adjusted to the order of submicrons.

7. The generator of claim 6 wherein the photon-emitting surface comprises a light-emitting diode.

8. The generator of claim 7 wherein the diode comprises a light-emitter surface.

9. The generator of claim 8 wherein the diode comprises a semi-conductor light-emitting surface.

10. The generator of claim 8 wherein the photovoltaic surface comprises a semiconductor surface disposed substantially coextensive and parallel with the diode surface.

11. The generator of claim 5 wherein said spacer is maintained fixed by a heat insulating interposed spacer.

12. The generator of claim 11 wherein said spacer comprises an array of parallel spacer elements transversely extending between said surfaces.

13. The generator of claim 5 wherein said surfaces are enclosed in a common evacuated housing.

14. The generator of claim 13 wherein said surfaces comprises arrays of laterally disposed chips held fixed by said spacer elements.
